(19) United States
(12) Patent Application Publication
(10) Pub. No.: US 2025/0125302 A1
(43) Pub. Date: Apr. 17, 2025

(54) SEMICONDUCTOR PACKAGE WITH NON-CONDUCTIVE SUPPORT LAYER

(71) Applicant: SAMSUNG ELECTRONICS CO., LTD., Suwon-si (KR)

(72) Inventors: Jing Cheng LIN, Suwon-si (KR); Youngkun Jee, Suwon-si (KR)

(73) Assignee: SAMSUNG ELECTRONICS CO., LTD., Suwon (KR)

(21) Appl. No.: 18/808,869

(22) Filed: Aug. 19, 2024

(30) Foreign Application Priority Data
Oct. 13, 2023 (KR) 10-2023-0137040

(51) Int. Cl. H01L 25/16; H01L 23/00; H01L 23/31; H10B 80/00

(52) U.S. Cl. CPC H01L 24/73; H01L 24/32; H01L 24/81; H01L 24/83; H01L 24/92; H01L 25/16; H01L 2224/32145; H01L 2224/73104; H01L 2224/81007; H01L 2224/81203; H01L 2224/83007; H01L 2224/83203; H01L 2224/9211; H01L 2225/06513; H01L 2225/06541; H01L 2924/1431; H01L 2924/1436; H01L 2924/3512; H01L 2924/3841; H10B 80/00

(57) ABSTRACT

A semiconductor package includes a first semiconductor chip including a plurality of upper pads, a non-conductive support layer on a top surface of the first semiconductor chip and including a plurality of openings, a second semiconductor chip on the first semiconductor chip and including a plurality of lower pads, a plurality of chip connecting terminals extending between the plurality of upper pads and the plurality of lower pads, and an insulation adhesive layer between the first semiconductor chip and the second semiconductor chip and at least partially covering the plurality of chip connecting terminals and the non-conductive support layer. A top surface of the non-conductive support layer is disposed closer to a bottom surface of the second semiconductor chip than top surfaces of the plurality of upper pads are disposed to the bottom surface of the second semiconductor chip.

### CROSS-REFERENCE TO RELATED APPLICATIONS

This application claims benefit of priority under 35 U.S.C. § 119 to Korean Patent Application No. 10-2023-0137040, filed on Oct. 13, 2023, in the Korean Intellectual Property Office, the disclosure of which is incorporated by reference herein in its entirety.

### BACKGROUND

### 1. Field

The present disclosure relates generally to semiconductor packages, and more particularly, to a semiconductor package with a non-conductive support layer.

### 2. Description of Related Art

According to rapid development in the electronics industry and increasing user demands, electronic devices may become more compact and/or multi-functional. Accordingly, a demand for miniaturization and/or multi-functionality of semiconductor chips used in the electronic devices may also increase. Consequently, there exists a need for further improvements in semiconductor packaging technology, as the need to mount high-capacity semiconductor chips within a limited structure of a semiconductor package may be constrained by the size and/or spacing of connection terminals. Improvements are presented herein. These improvements may also be applicable to other semiconductor technologies and the standards that employ these technologies.

### SUMMARY

One or more example embodiments of the present disclosure provide a semiconductor package with a non-conductive support layer having potentially improved reliability, when compared to related semiconductor packages.

According to an aspect of the present disclosure, a semiconductor package includes a first semiconductor chip including a plurality of upper pads, a non-conductive support layer on a top surface of the first semiconductor chip and including a plurality of openings, a second semiconductor chip on the first semiconductor chip and including a plurality of lower pads, a plurality of chip connecting terminals extending between the plurality of upper pads and the plurality of lower pads, and an insulation adhesive layer between the first semiconductor chip and the second semiconductor chip and at least partially covering the plurality of chip connecting terminals and the non-conductive support layer. Each of the plurality of chip connecting terminals is coupled with a corresponding upper pad from among the plurality of upper pads and a corresponding lower pad from among the plurality of lower pads through a corresponding opening from among the plurality of openings of the non-conductive support layer. Each of the plurality of upper pads includes a first horizontal area. Each of the plurality of lower pads includes a second horizontal area. The first horizontal area is larger than the second horizontal area. A top surface of the non-conductive support layer is disposed closer to a bottom surface of the second semiconductor chip than top surfaces of the plurality of upper pads are disposed to the bottom surface of the second semiconductor chip.

According to an aspect of the present disclosure, a semiconductor package includes a first semiconductor chip including a plurality of upper pads, a non-conductive support layer on a top surface of the first semiconductor chip and including a plurality of openings at least partially exposing the plurality of upper pads, a second semiconductor chip on the first semiconductor chip and including a plurality of lower pads, and a plurality of chip connecting terminals, each of the plurality of chip connecting terminals contacting and coupled with an upper pad from among the plurality of upper pads and a lower pad from among the plurality of lower pads. Each of the plurality of upper pads has a first horizontal width. Each of the plurality of lower pads has a second horizontal width. The second horizontal width is less than the first horizontal width. In a plan view, the second semiconductor chip includes a first chip center, a center region including the first chip center, and an edge region at least partially surrounding the center region. Each of the plurality of openings of the non-conductive support layer includes an opening center. Each of the plurality of upper pads includes a first pad center. Each of the plurality of lower pads includes a second pad center. In the edge region, in the plan view, at least one of the opening center, the first pad center, and the second pad center is spaced apart from remaining centers of the at least one of the opening center, the first pad center, and the second pad center in a direction away from the first chip center.

According to an aspect of the present disclosure, a semiconductor package includes a first semiconductor chip including a plurality of upper pads, a non-conductive support layer on a top surface of the first semiconductor chip and including a plurality of openings at least partially exposing the plurality of upper pads, a second semiconductor chip on the first semiconductor chip and including a plurality of lower pads, a plurality of chip connecting terminals, each of the plurality of chip connecting terminals contacting and coupled with an upper pad from among the plurality of upper pads and a lower pad from among the plurality of lower pads, and an insulation adhesive layer, between the first semiconductor chip and the second semiconductor chip, at least partially covering the plurality of chip connecting terminals and the non-conductive support layer, and protruding from sidewalls of the second semiconductor chip. Each of the plurality of upper pads has a first horizontal area. Each of the plurality of lower pads has a second horizontal area. The first horizontal area is larger than the second horizontal area. A top surface of the non-conductive support layer is disposed closer to a bottom surface of the second semiconductor chip than top surfaces of the plurality of upper pads are disposed to the bottom surface of the second semiconductor chip. A first length between the top surface of the non-conductive support layer and the bottom surface of the second semiconductor chip in a vertical direction is less than or equal to or less than a half of a second length between the top surface of the first semiconductor chip and the bottom surface of the second semiconductor chip.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1A is a plan view of a semiconductor package, according to embodiments;

FIG. 1B illustrates enlarged views of regions of FIG. 1A, according to embodiments;

FIG. 2A is a cross-sectional view of the semiconductor package taken along a line X1-X1′ of FIG. 1A, according to embodiments;

FIG. 2B is an enlarged view of a region indicated as EX1 in FIG. 2A, according to embodiments;

FIG. 2C is an enlarged view of a region indicated as EX2 in FIG. 2A, according to embodiments;

FIGS. 3A and 3B are cross-sectional views of a semiconductor package, according to embodiments;

FIGS. 4A and 4B are a plan view and a cross-sectional view of a semiconductor package, respectively, according to embodiments;

FIGS. 5A and 5B are a plan view and a cross-sectional view of a semiconductor package, respectively, according to embodiments;

FIGS. 6A and 6B are a plan view and a cross-sectional view of a semiconductor package, respectively, according to embodiments;

FIGS. 7A and 7B are a plan view and a cross-sectional view of a semiconductor package, respectively, according to embodiments; and

FIG. 8 is a cross-sectional view of a semiconductor package, according to embodiments.

### DETAILED DESCRIPTION OF THE DRAWINGS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, “surrounding”, “exposing”, and the like, another element or layer, the element or layer may cover, overlap, surround, and/or expose at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “CuAu”, “CuMg”, “CuNi”, “CuPd”, “CuRe”, “CuSn”, “CuW”, “CuZn”, “GaAs”, “InAs”, “InP”, “NiB”, “SiC”, “SiN”, “SiO”, “SiON”, “TaN”, “TiN”, “WC”, “WN”, and the like may refer to a material made of elements included in each of the terms and is not a chemical formula representing a stoichiometric relationship.

In the present disclosure, a vertical direction may refer to the Z direction, and a horizontal direction may refer to a direction perpendicular to the Z direction. Alternatively or additionally, a first horizontal direction and a second horizontal direction may refer to directions that intersect each other. For example, the first horizontal direction may be referred to as the X direction, and the second horizontal direction may be referred to as the Y direction.

Hereinafter, various embodiments of the present disclosure are described with reference to the accompanying drawings.

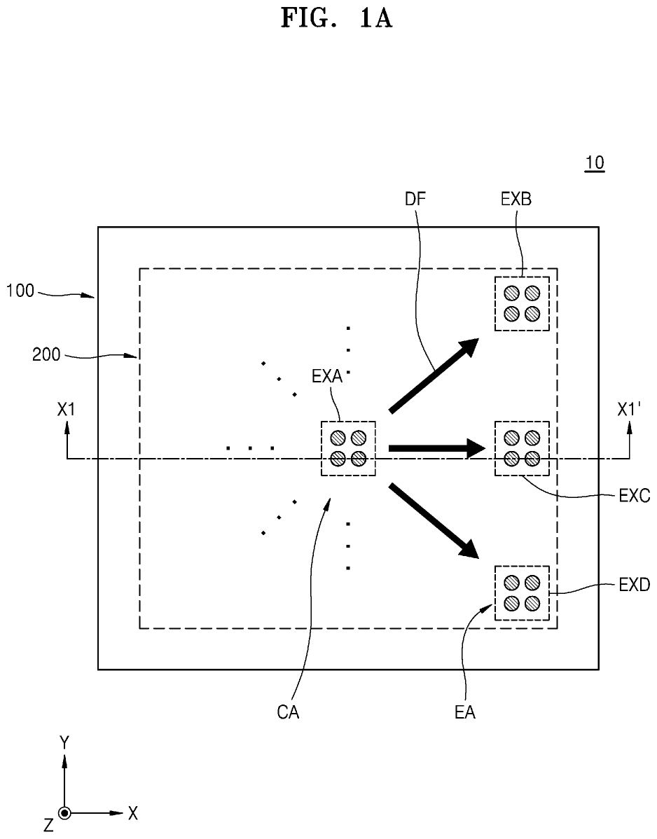

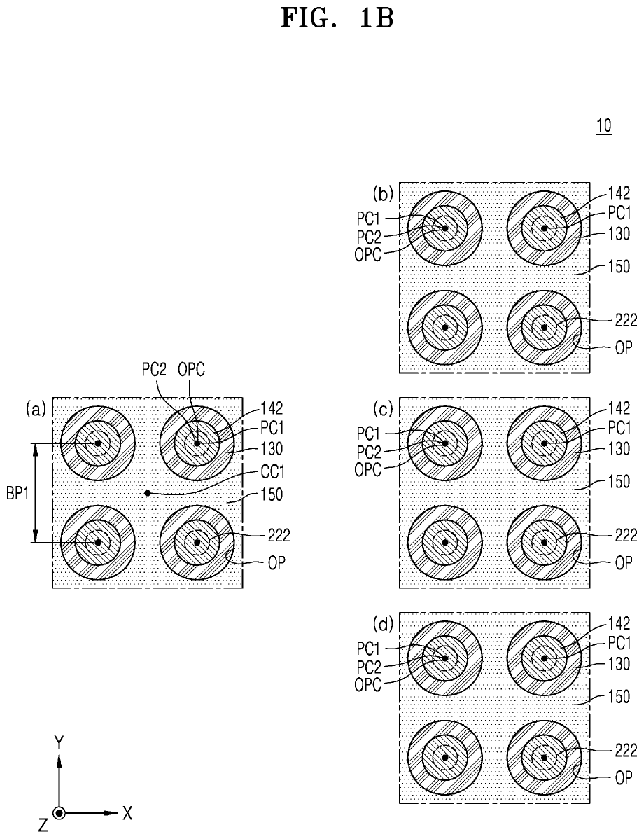

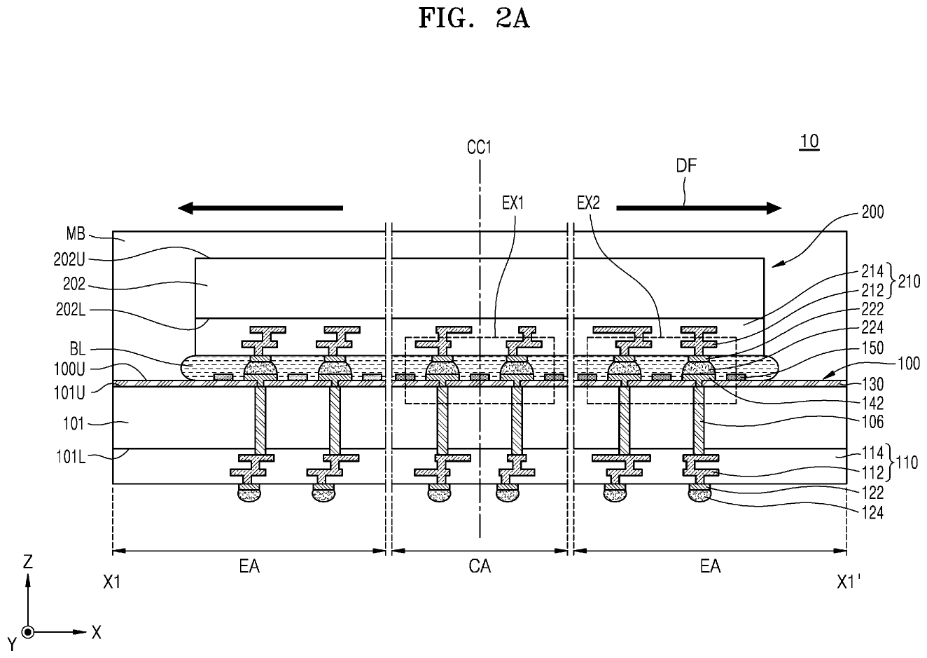

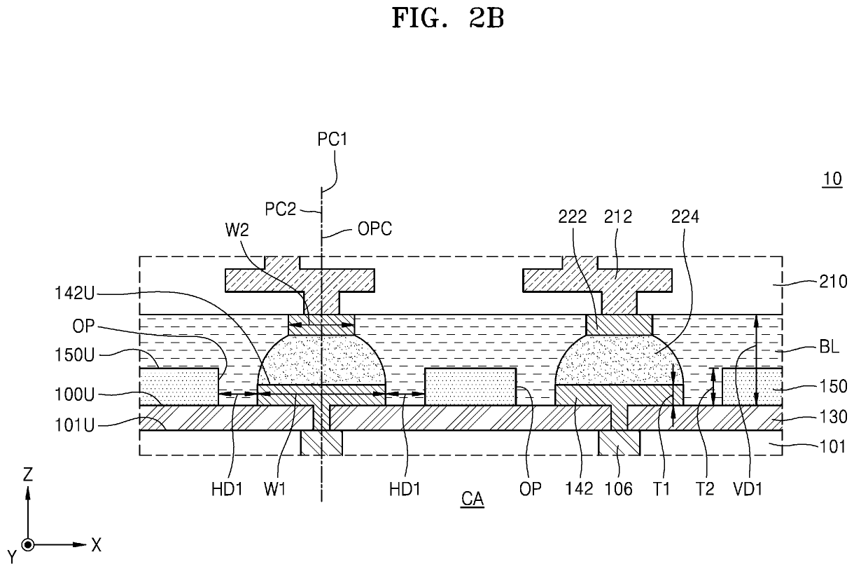

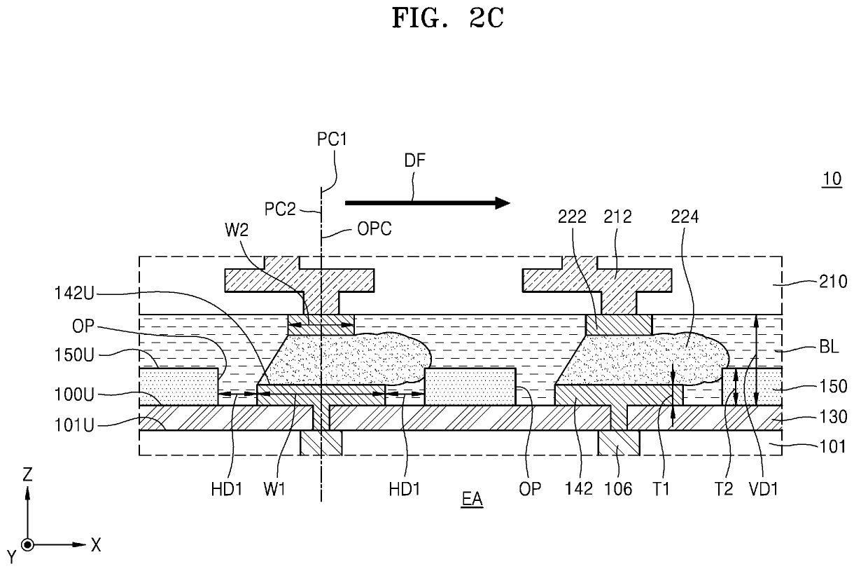

FIG. 1A is a plan view of a semiconductor package 10, according to embodiments. FIG. 1B illustrates enlarged views of regions indicated as EXA, EXB, EXC, and EXD in FIG. 1A in (a), (b), (c), and (d), respectively, according to embodiments. FIG. 2A is a cross-sectional view of the semiconductor package 10 taken along a line X1-X1′ of FIG. 1A, according to embodiments. FIG. 2B is an enlarged view of a region indicated as EX1 in FIG. 2A, according to embodiments. FIG. 2C is an enlarged view of a region indicated as EX2 in FIG. 2A, according to embodiments.

Referring to FIGS. 1A to 2C, the semiconductor package 10 may include a first semiconductor chip 100, a second semiconductor chip 200, a non-conductive support layer 150 on the first semiconductor chip 100, a plurality of chip connecting terminals 224 provided between the first semiconductor chip 100 and the second semiconductor chip 200, and an insulation adhesive layer BL that may at least partially fill a gap between the first semiconductor chip 100 and the second semiconductor chip 200.

According to embodiments, each of the first semiconductor chip 100 and the second semiconductor chip 200 may be and/or may include a memory chip and/or a logic chip. According to some embodiments, the first semiconductor chip 100 and the second semiconductor chip 200 may be chips of the same type. For example, each of the first semiconductor chip 100 and the second semiconductor chip 200 may be a memory chip. According to some embodiments, the first semiconductor chip 100 and the second semiconductor chip 200 may be chips of different types. For example, the first semiconductor chip 100 may be a logic chip and the second semiconductor chip 200 may be a memory chip.

The memory chip may be and/or may include, but not limited to, a volatile memory chip (e.g., dynamic random access memory (DRAM), static random access memory (SRAM), and the like) and/or a non-volatile memory chip (e.g., phase-change random access memory (PRAM), magneto-resistive random access memory (MRAM), ferroelectric random access memory (FeRAM), resistive random access memory (RRAM), and the like). The logic chip may be and/or may include, but not be limited to, a microprocessor, an analog device, a digital signal processor (DSP), and the like.

According to some embodiments, the first semiconductor chip 100 may be and/or may include a buffer chip for controlling high bandwidth memory (HBM) DRAM. The second semiconductor chip 200 may be and/or may include a plurality of second semiconductor chips 200 such as, but not limited to, memory cell chips having HBM DRAM cells that may be controlled by the first semiconductor chip 100. The first semiconductor chip 100 may be referred to as a buffer chip and/or a master chip, and the second semiconductor chip 200 may be referred to as a memory cell chip and/or a slave chip. According to some embodiments, the semiconductor package 10 may include the first semiconductor chip 100 and the plurality of second semiconductor chips 200 stacked on the first semiconductor chip 100. In such embodiments, the first semiconductor chip 100 and the plurality of second semiconductor chips 200 may be collectively referred to as an HBM DRAM device and/or an HBM DRAM chip.

According to embodiments, the width in a horizontal direction (e.g., the X direction and/or the Y direction) and the area of the first semiconductor chip 100 may be greater than the width in a horizontal direction (e.g., the X direction and/or the Y direction) and the area of the second semiconductor chip 200. Edges of the first semiconductor chip 100 may not be aligned with edges of the second semiconductor chip 200 in the vertical direction (e.g., Z direction). For example, in a plan view, the second semiconductor chip 200 may be disposed within an area defined by the edges of the first semiconductor chip 100. As another example, the second semiconductor chip 200 may vertically overlap the first semiconductor chip 100.

According to example embodiments, the first semiconductor chip 100 may include a first substrate 101, a first wiring layer 110, a plurality of first via electrodes 106, a first upper protective layer 130, a plurality of first upper pads 142, and a plurality of first lower pads 122.

According to some embodiments, the first substrate 101 may include a top surface 101U and a bottom surface 101L that may face each other. As used herein, the top surface 101U may be referred to as an inactive surface, and the bottom surface 101L may be referred to as an active surface. In some embodiments, the first semiconductor chip 100 may include a plurality of individual devices of various types disposed on the bottom surface 101L of the first substrate 101. The individual devices may include various microelectronic devices such as, but not limited to, a metal-oxide-semiconductor field effect transistor (MOSFET) (e.g., a complementary metal-insulator-semiconductor transistor (CMOS) transistor), a large scale integration (LSI) system, an image sensor (e.g., a CMOS imaging sensor (CIS)), a micro-electro-mechanical system (MEMS), an active device, a passive device, and the like.

According to some embodiments, the first substrate 101 may be a silicon (Si) wafer including crystalline silicon, polycrystalline silicon, amorphous silicon, and the like. According to some embodiments, the first substrate 101 may include a semiconductor element such as, but not limited to, germanium (Ge) and/or a compound semiconductor such as, but not limited to, silicon carbide (SiC), gallium arsenide (GaAs), indium arsenide (InAs), and indium phosphide (InP).

According to some embodiments, the first wiring layer 110 may be disposed on the bottom surface 101L of the first substrate 101. The first wiring layer 110 may include a first wiring structure 112 and a first lower insulation layer 114 surrounding the first wiring structure 112. For example, the first wiring structure 112 may be electrically connected to a plurality of individual devices formed on the active surface of the first substrate 101.

According to some embodiments, the first wiring structure 112 may include a metal wiring layer extending in a horizontal direction (e.g., the X direction and/or the Y direction) and a via plug extending in the vertical direction (e.g., Z direction). For example, the first wiring structure 112 may include a plurality of metal wiring layers arranged at different vertical levels. As used herein, a vertical level may refer to a distance in the vertical direction (e.g., Z direction or −Z direction) from the top surface 101U of the first substrate 101.

According to some embodiments, the first wiring structure 112 may include metals such as, but not limited to, copper (Cu), aluminum (Al), tungsten (W), titanium (Ti), tantalum (Ta), molybdenum (Mo), cobalt (Co), and nickel (Ni), alloys thereof, and/or nitrides thereof. According to some embodiments, the first lower insulation layer 114 may include a high density plasma (HDP) oxide layer, a tetraethoxysilane (TEOS) oxide layer, a Tonen SilaZene (TOSZ) layer, a spin-on-glass (SOG) layer, an undoped silica glass (USG) layer, or a low-k dielectric layer. However, the present disclosure is not limited thereto.

According to some embodiments, the plurality of first via electrodes 106 may penetrate through the first substrate 101 and be connected to the first wiring structure 112. According to some embodiments, the plurality of first via electrodes 106 may each include a conductive plug and a conductive barrier film surrounding the conductive plug. The conductive plug may include, but not be limited to, copper (Cu), tungsten (W), and the like. For example, the conductive plug may include, but not be limited to, at least one of copper (Cu), copper-tin (CuSn), copper-magnesium (CuMg), copper-nickel (CuNi), copper-zinc (CuZn), copper-palladium (CuPd), copper-gold (CuAu), copper-rhenium (CuRe), copper-tungsten (CuW), and tungsten (W). The conductive barrier film may include at least one of tungsten (W), tungsten-nitrogen (WN), tungsten-carbon (WC), titanium (Ti), titanium-nitrogen (TiN), tantalum (Ta), tantalum-nitrogen (TaN), ruthenium (Ru), cobalt (Co), manganese (Mn), nickel (Ni), and nickel-boron (NiB). The conductive barrier film may include a single layer and/or multiple layers.

According to some embodiments, the plurality of first lower pads 122 may be arranged on the bottom surface of the first wiring layer 110. The plurality of first lower pads 122 may be electrically connected to the plurality of first via electrodes 106 through the first wiring structure 112 of the first wiring layer 110. According to some embodiments, the plurality of first lower pads 122 may include, but not be limited to, at least one of aluminum (Al), copper (Cu), nickel (Ni), tungsten (W), platinum (Pt), and gold (Au).

According to some embodiments, the plurality of first lower pads 122 may be connected to a plurality of connection terminals 124, respectively. For example, the plurality of connection terminals 124 may be configured to be electrically connected to a base substrate outside the semiconductor package 10. According to some embodiments, the plurality of connection terminals 124 may be and/or may include, for example, bumps, solder balls, and the like.

According to some embodiments, the first upper protective layer 130 may be disposed on the top surface 101U of the first substrate 101. For example, the first upper protective layer 130 may be disposed to cover the first substrate 101 while opening the plurality of first upper pads 142. According to some embodiments, the first upper protective layer 130 may include a single layer and/or multiple layers. The top surface of the first upper protective layer 130 may include the top surface 100U of the first semiconductor chip 100.

According to some embodiments, the first upper protective layer 130 may include, but not be limited to, silicon oxide (SiO), silicon nitride (SiN), silicon oxynitride (SiON), and a polymer material. For example, the polymer material may include, but not be limited to, silicone, epoxy, benzocyclobutene (BCB), polyimide (PI), polybenzoxazole (PBO), and the like.

According to some embodiments, the plurality of first upper pads 142 may be arranged to be spaced apart from one another on the top surface 101U of the first substrate 101. For example, the plurality of first upper pads 142 may each include a pad portion extending in the horizontal direction (e.g., X direction) on the first upper protective layer 130 and a via portion that may penetrate through the first upper protective layer 130 and may contact a corresponding first via electrode 106 from among the plurality of first via electrodes 106. As another example, the pad portion of each of the plurality of first upper pads 142 may be disposed on the top surface 100U of the first semiconductor chip 100.

According to some embodiments, the plurality of first upper pads 142 may include, but not be limited to, at least one of copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru).

According to embodiments, the second semiconductor chip 200 may include a second substrate 202, a second wiring layer 210, and a plurality of second lower pads 222. The second semiconductor chip 200 may include components that may be substantially identical and/or may be similar in many respects to components of the first semiconductor chip 100, as described above. Furthermore, the components of the second semiconductor chip 200 may include substantially similar and/or the same materials as corresponding components of the first semiconductor chip 100, as described above.

According to some embodiments, the second substrate 202 may include a top surface 202U and a bottom surface 202L that may face each other. The bottom surface 202L may be referred to as an active surface, and the top surface 202U may be referred to as an inactive surface. The second semiconductor chip 200 may include a plurality of individual devices on the bottom surface 202L of the second substrate 202.

According to some embodiments, the second wiring layer 210 may be disposed on the bottom surface 202L of the second substrate 202. The second wiring layer 210 may include a second wiring structure 212 and a second lower insulation layer 214 surrounding the second wiring structure 212.

According to some embodiments, the plurality of second lower pads 222 may be arranged on the bottom surface of the second wiring layer 210 to be spaced apart from one another. The plurality of second lower pads 222 may contact and be connected to the second wiring structure 212 and may be electrically connected to a plurality of individual devices formed on the active surface of the second substrate 202 through the second wiring structure 212.

According to embodiments, the plurality of chip connecting terminals 224 may be provided between the first semiconductor chip 100 and the second semiconductor chip 200. The plurality of chip connecting terminals 224 may extend between the plurality of first upper pads 142 and the plurality of second lower pads 222. The plurality of chip connecting terminals 224 may each contact and be connected to an upper pad from among the plurality of first upper pads 142 of the first semiconductor chip 100 and a lower pad from among the plurality of second lower pads 222 of the plurality of second semiconductor chips 200. For example, the plurality of chip connecting terminals 224 may at least partially overlap a corresponding first upper pad 142 from among the plurality of first upper pads 142 and a corresponding second lower pad 222 from among the plurality of second lower pads 222 in the vertical direction.

According to some embodiments, the plurality of chip connecting terminals 224 may include, but not be limited to, tin (Sn), zinc (Zn), and the like. According to some embodiments, zinc (Zn) may be included in an amount from about 1 percent by weight (wt %) to about 7 wt % with respect to the total weight of the plurality of chip connecting terminals 224. In some embodiments, an intermetallic compound may be formed at an interface between the plurality of chip connecting terminals 224 and the plurality of first upper pads 142 and at an interface between the plurality of chip connecting terminals 224 and the plurality of second lower pads 222 in a relatively small amount. The intermetallic compound may have a material composition similar to the plurality of chip connecting terminals 224. Consequently, an electrical reliability of the semiconductor package 10 may be potentially improved, when compared to related semiconductor packages.

According to embodiments, the non-conductive support layer 150 may be disposed on the top surface 100U of the first semiconductor chip 100. The non-conductive support layer 150 may have a plurality of openings OP that may respectively expose the plurality of first upper pads 142 on the first semiconductor chip 100. According to embodiments, the plurality of first upper pads 142 may be spaced apart from one another in the horizontal direction (e.g., the X direction and/or the Y direction) with the non-conductive support layer 150 therebetween. In a plan view, the non-conductive support layer 150 may surround the plurality of first upper pads 142. According to embodiments, the plurality of chip connecting terminals 224 may each contact and be connected to a corresponding first upper pad 142 from among the plurality of first upper pads 142 and a corresponding second lower pad 222 from among the plurality of second lower pads 222 through a corresponding opening OP from among the plurality of openings OP.

According to some embodiments, the non-conductive support layer 150 may include, but not be limited to, a silicon oxide (SiO) film, a silicon nitride (SiN) film, a silicon oxynitride (SiON) film, and the like. For example, the non-conductive support layer 150 may be formed by forming an insulation material film covering the top surface 100U of the first semiconductor chip 100 and top surfaces 142U of the plurality of first upper pads 142 and by removing a portion of the insulation material film covering the plurality of first upper pads 142 through patterning, for example.

According to embodiments, the insulation adhesive layer BL may be provided between the first semiconductor chip 100 and the second semiconductor chip 200 and may surround the plurality of chip connecting terminals 224. According to some embodiments, the insulation adhesive layer BL may include a portion contacting a top surface 150U of the non-conductive support layer 150, portions contacting the inner walls of the plurality of openings OP, a portion contacting the first upper protective layer 130, a portion contacting the bottom surface of the second semiconductor chip 200, portions contacting the sidewalls of the plurality of first upper pads 142, and portions contacting the sidewalls of the plurality of second lower pads 222.

According to some embodiments, the insulation adhesive layer BL may protrude from the sidewalls of the second semiconductor chip 200. According to some embodiments, the second semiconductor chip 200 may have a first chip center CC1, and the insulation adhesive layer BL may protrude from the sidewalls of the semiconductor chip 200 radially from the first chip center CC1. For example, in a plan view, the outer boundary of the second semiconductor chip 200 may be included within the outer boundary of the insulation adhesive layer BL.

According to some embodiments, the insulation adhesive layer BL may include, but not be limited to, a non-conductive film, a non-conductive paste, an insulation polymer, an epoxy resin, and the like.

According to embodiments, the semiconductor package 10 may further include a mold layer MB surrounding the second semiconductor chip 200 and the insulation adhesive layer BL on the first semiconductor chip 100. The mold layer MB may include, for example, an epoxy mold compound (EMC). However, the present disclosure is not limited thereto.

According to some embodiments, the second semiconductor chip 200 may be mounted on the center of the first semiconductor chip 100. In such embodiments, the first semiconductor chip 100 and the second semiconductor chip 200 may share the center point. According to some embodiments, the first chip center CC1 of the second semiconductor chip 200 may be offset from the center of the first semiconductor chip 100. According to embodiments, the second semiconductor chip 200 may include, in a plan view, a center region CA including the first chip center CC1 and an edge region EA around the center region CA.

According to some embodiments, the first semiconductor chip 100 and the second semiconductor chip 200 may be formed individually and bonded to each other through the insulation adhesive layer BL. According to some embodiments, after the plurality of chip connecting terminals 224 are respectively attached to the plurality of second lower pads 222 of the second semiconductor chip 200, a preliminary adhesive layer may be formed on the bottom surface of the second semiconductor chip 200 to a thickness sufficient to at least partially cover the plurality of chip connecting terminals 224. Thereafter, the bottom surface of the second semiconductor chip 200 may be aligned to face the top surface 100U of the first semiconductor chip 100, and the first semiconductor chip 100 and the second semiconductor chip may be bonded to each other through thermal compression, thereby forming the insulation adhesive layer BL. During a thermal compression bonding process of the first semiconductor chip 100 and the second semiconductor chip 200, the preliminary adhesive layer may spread radially from the first chip center CC1, and the preliminary adhesive layer may flow more significantly in the edge region EA than in the center region CA. The flow of the preliminary adhesive layer may occur more significantly as the distance from the first chip center CC1 increases in a plan view. In FIGS. 1A, 2A, and 2C, a flow direction DF of the preliminary adhesive layer is indicated by a thick arrow. For example, the flow direction DF of the preliminary adhesive layer may be opposite to a direction toward the first chip center CC1 in a plan view. As used herein, the flow direction DF of the preliminary adhesive layer may be referred to as the flow direction DF for convenience.

According to some embodiments, the plurality of first upper pads 142 may each have a first pad center PC1, and the plurality of second lower pads 222 may each have a second pad center PC2. Referring to FIG. 2B, in the center region CA, since the influence on the flow of the preliminary adhesive layer due to a thermal compression process may be relatively small, the plurality of chip connecting terminals 224 may be arranged radially symmetrically around the first pad center PC1 and the second pad center PC2. Referring to FIG. 2C, in the edge region EA, since the influence on the flow of the preliminary adhesive layer due to the thermal compression process may be relatively large, the plurality of chip connecting terminals 224 may be arranged asymmetrically around the first pad center PC1 and the second pad center PC2. For example, in the edge region EA, the plurality of chip connecting terminals 224 may have a shape protruding in the flow direction DF based on from first pad center PC1 and the second pad center PC2.

According to some embodiments, the plurality of second lower pads 222 may be spaced apart from one other by a first pitch BP1. The first pitch BP1 may be, for example, about 30 microns (micrometers or μm) or less. In some embodiments, the first pitch BP1 may be within a range from about 10 μm to about 30 μm, and thus, the plurality of chip connecting terminals 224 attached to the plurality of second lower pads 222 may also be spaced apart from one another by a fine pitch. According to embodiments, the non-conductive support layer 150 may be disposed between the plurality of first upper pads 142 and may potentially reduce and/or prevent short-circuits between chip connecting terminals 224 adjacent to each other from among the plurality of chip connecting terminals 224.

According to some embodiments, the plurality of first upper pads 142 may each have a smaller planar area than a corresponding lower pad 222 from among the plurality of second lower pads 222. The plurality of first upper pads 142 may each have a first horizontal width W1, and the plurality of second lower pads 222 may each have a second horizontal width W2. According to some embodiments, the first horizontal width W1 may be greater than the second horizontal width W2. For example, the top surfaces 142U of the plurality of first upper pads 142 may contact the plurality of chip connecting terminals 224 and may provide a relatively large area for forming the interface. Consequently, when the first semiconductor chip 100 and the second semiconductor chip 200 are bonded to each other, the top surfaces 142U of the plurality of first upper pads 142 may induce relatively large consumption of the plurality of chip connecting terminals 224 due to wetting at the interface. And as result, the amount of the plurality of chip connecting terminals 224 spreading in lateral directions during bonding may be potentially reduced, thereby improving the reliability of the semiconductor package 10, when compared to a related semiconductor package.

According to some embodiments, the plurality of openings OP may each have a horizontal width greater than the first horizontal width W1. According to some embodiments, the plurality of first upper pads 142 may be spaced apart from the non-conductive support layer 150. The first plurality of upper pads 142 may not contact the non-conductive support layer 150. The sidewall of each of the plurality of first upper pads 142 may be spaced apart from the inner wall of a corresponding opening OP from among the plurality of openings OP. According to some embodiments, in a plan view, the plurality of first upper pads 142 may each be disposed within a corresponding opening OP from among the plurality of openings OP. For example, the periphery of a portion of the first upper protective layer 130 that may vertically overlap the plurality of first upper pads 142 may be exposed through the plurality of openings OP without being covered by the non-conductive support layer 150. The insulation adhesive layer BL may include a portion provided between the plurality of first upper pads 142 and the non-conductive support layer 150 that may be spaced apart from each other. The portion of the insulation adhesive layer BL provided between the plurality of first upper pads 142 and the non-conductive support layer 150 may contact the sidewall of each of the plurality of first upper pads 142, the inner wall of each of the plurality of openings OP, and an upper surface of the first upper protective layer 130.

The plurality of openings OP may have an opening center OPC. According to some embodiments, the opening center OPC, the first pad center PC1, and the second pad center PC2 may overlap one another. For example, in a plan view, the plurality of first upper pads 142 may each share the center point with a corresponding opening OP from among the plurality of openings OP and a corresponding second lower pad 222 from among the plurality of second lower pads 222. As another example, in a plan view, the boundary of an upper pad from among the plurality of first upper pads 142, the boundary of a corresponding opening OP from among the plurality of openings OP, and the boundary of a corresponding second lower pad 222 from among the plurality of second lower pads 222 may have concentric-circular shapes. According to some embodiments, a first horizontal distance HD1, which may be a distance between the sidewall of each of the plurality of first upper pads 142 and the inner wall of a corresponding opening OP from among the plurality of openings OP in a horizontal direction (e.g., the X direction and/or the Y direction) may be constant with respect to the first pad center PC1 regardless of the azimuth. According to some embodiments, in the center region CA and the edge region EA, the plurality of first upper pads 142 may each be spaced apart from the non-conductive support layer 150 by the first horizontal distance HD1.

The plurality of first upper pads 142 may have a first thickness T1, which may be a length in the vertical direction (e.g., Z direction), and the non-conductive support layer 150 may have a second thickness T2, which may be a length in the vertical direction (e.g., Z direction). According to some embodiments, the second thickness T2 may be greater than the first thickness T1. For example, the top surface 150U of the non-conductive support layer 150 may be located at a higher vertical level than the top surface 142U of the plurality of first upper pads 142. As another example, the top surface 150U of the non-conductive support layer 150 may be closer to the bottom surface of the second semiconductor chip 200 than the top surface 142U of the plurality of first upper pads 142 is to the bottom surface of the second semiconductor chip 200. According to embodiments, the non-conductive support layer 150 may be disposed between the plurality of chip connecting terminals 224 and may serve as a dam preventing the plurality of chip connecting terminals 224 from being spread due to compression when the first semiconductor chip 100 and the second semiconductor chip 200 are bonded to each other, thereby potentially reducing and/or preventing short-circuits between the chip connecting terminals 224 adjacent to each other.

According to some embodiments, the top surface of the first semiconductor chip 100 may be spaced apart from the bottom surface of the second semiconductor chip 200 by a first vertical distance VD1 in the vertical direction (e.g., Z direction). As used herein, the first vertical distance VD1 may be referred to as a joint gap. For example, the first vertical distance VD1 may be from about 6 μm to about 20 μm.

According to some embodiments, the second thickness T2 of the non-conductive support layer 150 may be less than or equal to a half of the first vertical distance VD1. When the second thickness T2 exceeds the half of the first vertical distance VD1, the reliability of bonding between the first semiconductor chip 100 and the second semiconductor chip 200 may be deteriorated. The non-conductive support layer 150 of the semiconductor package 10, according to some embodiments, may secure a sufficient distance from the bottom surface of the second semiconductor chip 200, thereby potentially reducing and/or preventing short-circuits between the plurality of chip connecting terminals 224 without deteriorating bonding reliability, when compared to related semiconductor devices.

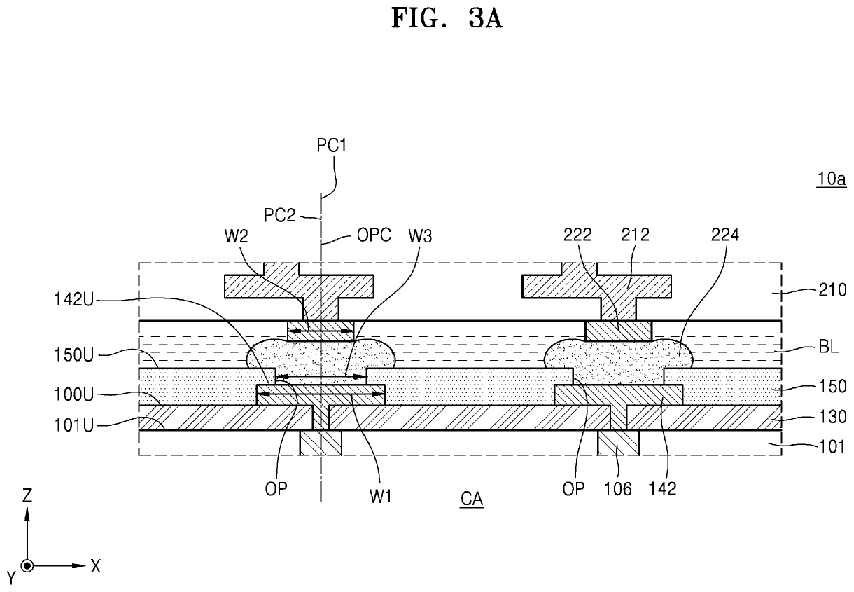

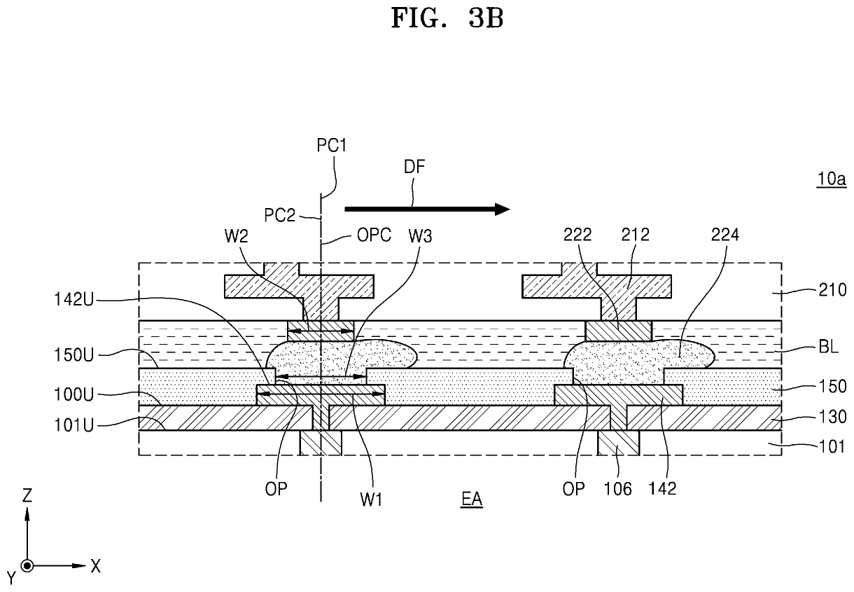

FIGS. 3A and 3B are cross-sectional views of a semiconductor package 10a, respectively, according to some embodiments. Referring to FIG. 3A, a region corresponding to a region indicated by EX1 in FIG. 2A is illustrated. Referring to FIG. 3B, a region corresponding to EX2 in FIG. 2A is illustrated. Elements indicated in FIGS. 3A and 3B with the same reference numerals as those in FIGS. 1A to 2C may denote the same elements, and as such, repeated descriptions thereof described above with reference to FIGS. 1A to 2C may be omitted for the sake of brevity.

Referring to FIGS. 3A and 3B, the configuration of semiconductor package 10a may be similar in many respects to the configuration of the semiconductor package 10 described above with reference to FIGS. 1A to 2C, and may include additional features not mentioned above. For example, the non-conductive support layer 150 of the semiconductor package 10a may contact the plurality of first upper pads 142.

According to some embodiments, the plurality of openings OP may each have a third horizontal width W3 that may be smaller than the first horizontal width W1. The non-conductive support layer 150 may cover the sidewalls and edges of the top surface 142U of each of the plurality of first upper pads 142. For example, the non-conductive support layer 150 may include a portion that may vertically overlap the plurality of first upper pads 142. An open portion of the top surface 142U of each the plurality of first upper pads 142 that may not be covered by the non-conductive support layer 150 (e.g., a portion exposed through a corresponding opening OP from among the plurality of openings OP) may contact a corresponding chip connecting terminal 224 from among the plurality of chip connecting terminals 224.

According to some embodiments, the plurality of chip connecting terminals 224 may each contact the inner wall of a corresponding opening OP from among the plurality of openings OP. According to some embodiments, the plurality of chip connecting terminals 224 may each include a portion that may contact and vertically overlap the non-conductive support layer 150. According to some embodiments, the thickness of a first portion of each of the plurality of chip connecting terminals 224 in contact with the plurality of first upper pads 142 in the vertical direction (e.g., Z direction) may be greater than the thickness of a second portion of each of the plurality of chip connecting terminals 224 vertically overlapping the non-conductive support layer 150. For example, the thickness of the first portion in the vertical direction (e.g., Z direction) may be a distance between the top surfaces 142U of the plurality of first upper pads 142 and the bottom surfaces of the plurality of second lower pads 222 in the vertical direction (e.g., Z direction).

According to some embodiments, the third horizontal width W3 may be smaller than the first horizontal width W1. According to some embodiments, the third horizontal width W3 may be greater than the second horizontal width W2 of each of the plurality of second lower pads 222.

The semiconductor package 10a, according to embodiments, may be designed such that the area of an exposed portion of the top surface 142U of each of the plurality of first upper pads 142 is greater than the area of a corresponding second lower pad 222 from among the plurality of second lower pads 222 in order to induce consumption of the plurality of chip connecting terminals 224 and reduce the thickness of the plurality of chip connecting terminals 224 in the vertical direction (e.g., Z direction) through the non-conductive support layer 150 covering edge portions of the plurality of first upper pads 142. Consequently, cracks in the plurality of chip connecting terminals 224 may be potentially reduced and/or prevented when an external shock is applied thereto, compared to related semiconductor packages.

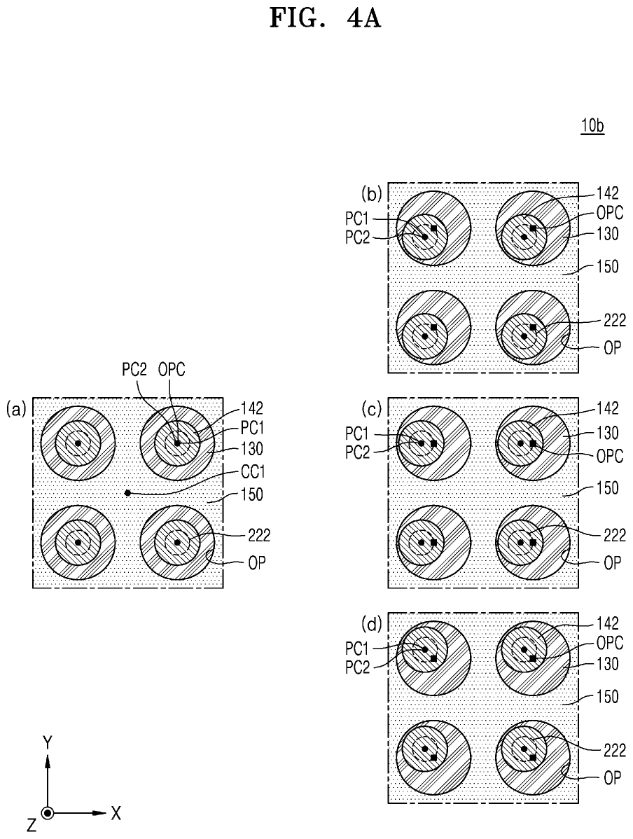

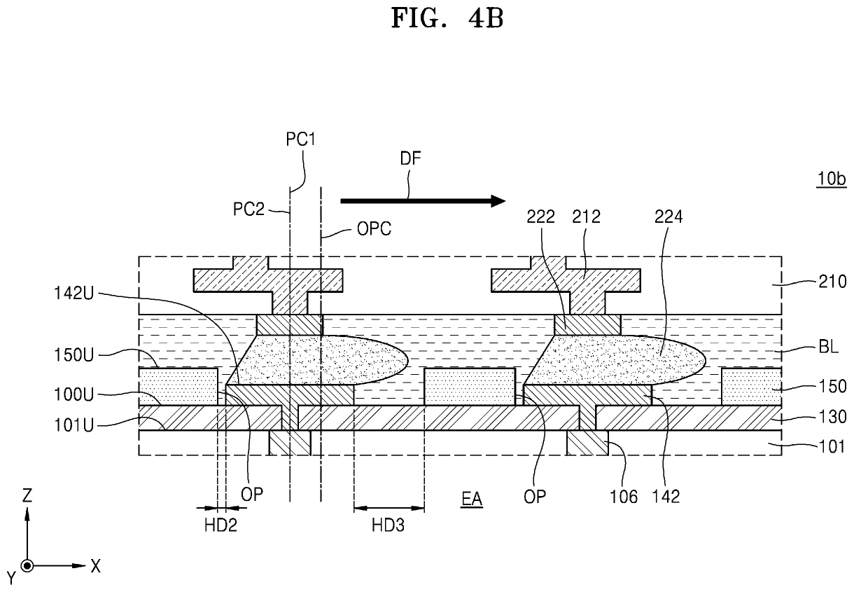

FIGS. 4A and 4B are a plan view and a cross-sectional view of a semiconductor package 10b, respectively, according to some embodiments. Referring to FIG. 4A, portions corresponding to local regions indicated as EXA, EXB, EXC, and EXD in FIG. 1A are illustrated in (a), (b), (c), and (d), respectively, according to embodiments. Referring to FIG. 4B, a portion corresponding to a local region indicated as EX2 in FIG. 2A is illustrated. Elements indicated in FIGS. 4A and 4B with the same reference numerals as those in FIGS. 1A to 2C may denote the same elements, and as such, repeated descriptions thereof described above with reference to FIGS. 1A to 2C may be omitted for the sake of brevity.

Referring to FIGS. 4A and 4B, the configuration of semiconductor package 10b may be similar in many respects to the configuration of the semiconductor package 10 described above with reference to FIGS. 1A to 2C, and may include additional features not mentioned above. For example, in the edge region EA of the semiconductor package 10b, the opening center OPC may be located farther from the first chip center CC1 than the first pad center PC1 and the second pad center PC2 are located from the first chip center CC1.

According to some embodiments, in the edge region EA, the first pad center PC1 and the second pad center PC2 may overlap each other, and the opening center OPC of each of the plurality of openings OP may be spaced apart from a corresponding first pad center PC1 and a corresponding second pad center PC2 in the flow direction DF. According to some embodiments, the first pad center PC1 and the second pad center PC2 may be located closer to the first chip center CC1 than the opening center OPC is located to the first chip center CC1. In the edge region EA, the sidewall of each of the plurality of first upper pads 142 may include a first portion facing the first chip center CC1 and a second portion opposite to the first portion.

According to some embodiments, in the edge region EA, the first portion may be disposed closer to the inner wall of a corresponding opening OP from among the plurality of openings OP than the second portion is disposed to the inner wall of the corresponding opening OP. According to some embodiments, the first portion may be spaced apart in the flow direction DF by a second horizontal distance HD2 from the inner wall of a corresponding opening OP from among the plurality of openings OP, and the second portion may be spaced apart in the flow direction DF by a third horizontal distance HD3 from the inner wall of a corresponding opening OP from among the plurality of openings OP. According to some embodiments, the third horizontal distance HD3 may be greater than the second horizontal distance HD2. In each of the plurality of openings OP, a margin in the flow direction DF may be secured between a corresponding chip connecting terminal 224 from among the plurality of chip connecting terminals 224 and the non-conductive support layer 150, and thus, the reliability of the semiconductor package 10b may be potentially improved when compared to related semiconductor packages.

According to some embodiments, in the center region CA, the plurality of chip connecting terminals 224 may receive relatively less spreading force, and thus, the opening center OPC may overlap the first pad center PC1 and the second pad center PC2. For example, the distance between each of the plurality of first upper pads 142 and the inner wall of a corresponding opening OP from among the plurality of openings OP may be constant regardless of the azimuth with respect to the first chip center CC1. As another example, in center region, the distance between each of the plurality of first upper pads 142 and the inner wall of a corresponding opening OP from among the plurality of openings OP may be substantially similar and/or the same regardless of the azimuth with respect to the opening center OPC.

According to some embodiments, the degree to which the opening center OPC is separated from the first pad center PC1 and the second pad center PC2 may vary depending on the distance from the first chip center CC1. For example, a first difference between the third horizontal distance HD3 and the second horizontal distance HD2 in a first region adjacent to the first chip center CC1 may be smaller than a second difference between the third horizontal distance HD3 and the second horizontal distance HD2 in a second region separated relatively far from the first chip center CC1.

FIGS. 4A and 4B show that a first separation distance, which may be the distance between the opening center OPC and the first pad center PC1 and the second pad center PC2, may be substantially similar and/or the same distance in all of local regions shown in FIGS. 4A and 4B. According to some embodiments, in a plan view, the semiconductor package 10b may include a plurality of groups of local regions divided according to distances from the first chip center CC1. In a group of local regions having the same distance from the first chip center CC1, the opening centers OPC of openings OP may be separated from the first pad center PC1 and the second pad center PC2 by the same first separation distance. For example, the same first separation distance may be applied to at least some of the plurality of openings OP. Although FIG. 4A shows that each local region includes four (4) openings OP, four (4) first upper pads 142, and four (4) second lower pads 222, the present disclosure is not limited thereto. For example, each local region may include more (e.g., more than four (4)), less (e.g., less than four (4)), and/or different amounts of openings, upper pads, and/or lower pads without departing from the scope of the present disclosure. As another example, the semiconductor package 10b may include groups of local regions include more regions or less regions than those illustrated in FIGS. 4A and 4B.

According to some embodiments, the first separation distance of the plurality of openings OP may gradually increase as the distance from the first chip center CC1 increases. For example, the first separation distance may be proportional to the distance from the first chip center CC1.

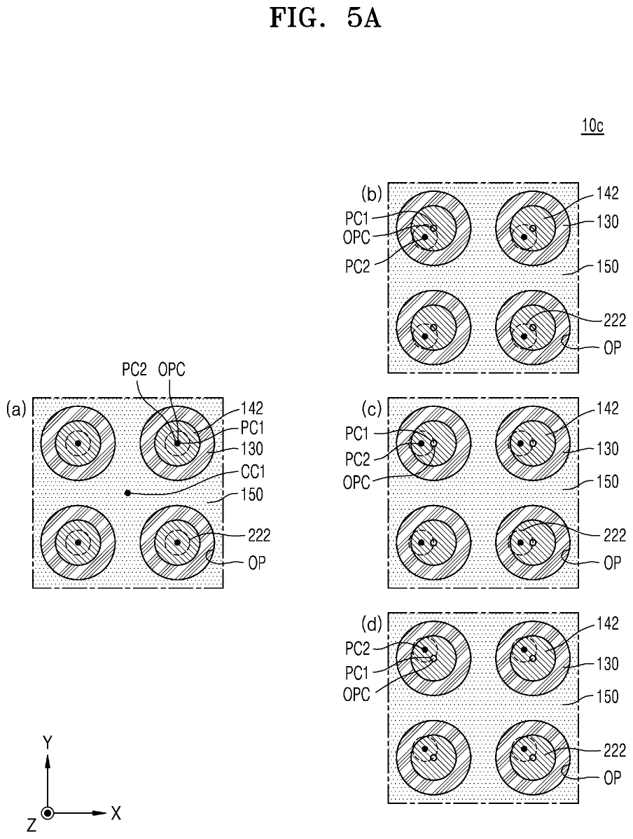

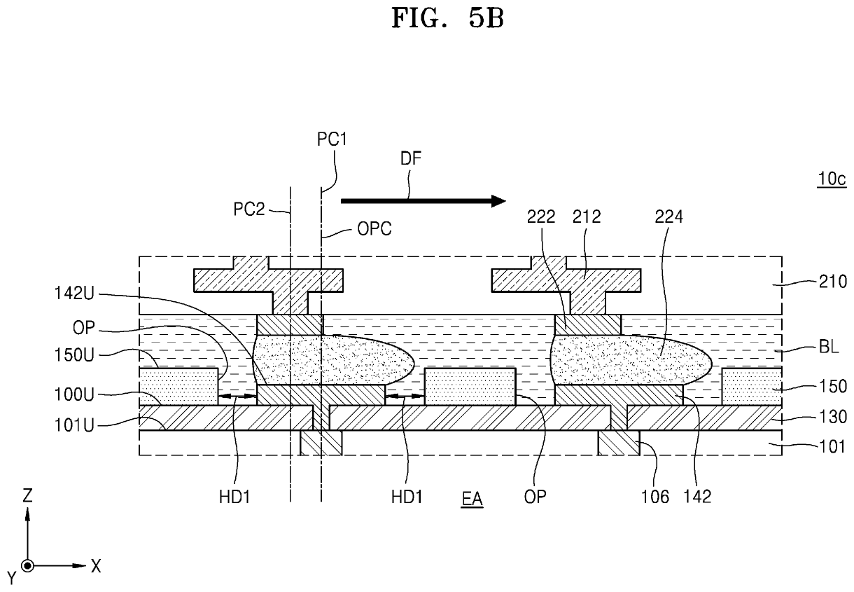

FIGS. 5A and 5B are a plan view and a cross-sectional view of a semiconductor package 10c, respectively, according to some embodiments. Referring to FIG. 5A, portions corresponding to the local regions indicated as EXA, EXB, EXC, and EXD in FIG. 1A are illustrated in (a), (b), (c), and (d), respectively. Referring to FIG. 5B, a portion corresponding to the local region indicated as EX2 in FIG. 2A is illustrated. Elements indicated in FIGS. 5A and 5B with the same reference numerals as those in FIGS. 1A to 2C may denote the same elements, and as such, repeated descriptions thereof described above with reference to FIGS. 1A to 2C may be omitted for the sake of brevity.

Referring to FIGS. 5A and 5B, the configuration of semiconductor package 10c may be similar in many respects to the configuration of the semiconductor package 10 described above with reference to FIGS. 1A to 2C, and may include additional features not mentioned above. For example, in the edge region EA of the semiconductor package 10c, the second pad center PC2 may be located closer to the first chip center CC1 than the opening center OPC and the first pad center PC1 are located to the first chip center CC1.

According to some embodiments, in the edge region EA, the second pad center PC2 may be spaced apart from the opening center OPC and the first pad center PC1 in the flow direction DF. According to some embodiments, the opening center OPC and the first pad center PC1 may overlap each other.

According to some embodiments, in a plan view, each of the plurality of second lower pads 222 may be located closer to the first chip center CC1 than a corresponding first upper pad 142 from among the plurality of first upper pads 142 is located to the first chip center CC1. Therefore, a portion of the top surface 142U of each of the plurality of first upper pads 142 that may not vertically overlap a corresponding second lower pad 222 from among the plurality of second lower pads 222 may have a margin in the flow direction DF. When the first semiconductor chip 100 and the second semiconductor chip 200 are bonded to each other, the plurality of chip connecting terminals 224 may each be seated on portions of the top surface 142U of each of the plurality of first upper pads 142 close to the first chip center CC1 and spread in the flow direction DF due to compression, and as such, the margin may contact the plurality of chip connecting terminals 224 and may induce relatively stable wetting, when compared to related semiconductor packages.

According to some embodiments, a second separation distance, which may be the distance between the second pad center PC2 and the opening center OPC and the first pad center PC1, may vary depending on the distance from the first chip center CC1. For example, the second separation distance in the first region adjacent to the first chip center CC1 may be smaller than the second separation distance in the second region relatively far from the first chip center CC1 than the first region is.

Although FIGS. 5A and 5B show that the second separation distance may be the same in all of local regions shown in FIGS. 5A and 5B, the present disclosure is not limited thereto. For example, the second separation distance may gradually increase as the distance from the first chip center CC1 increases. As another example, the second separation distance may be proportional to the distance from the first chip center CC1.

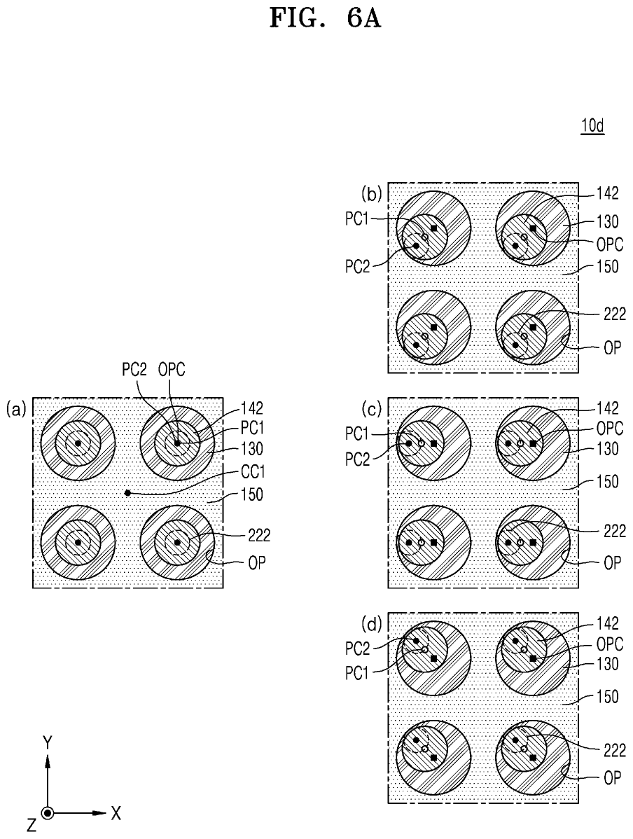

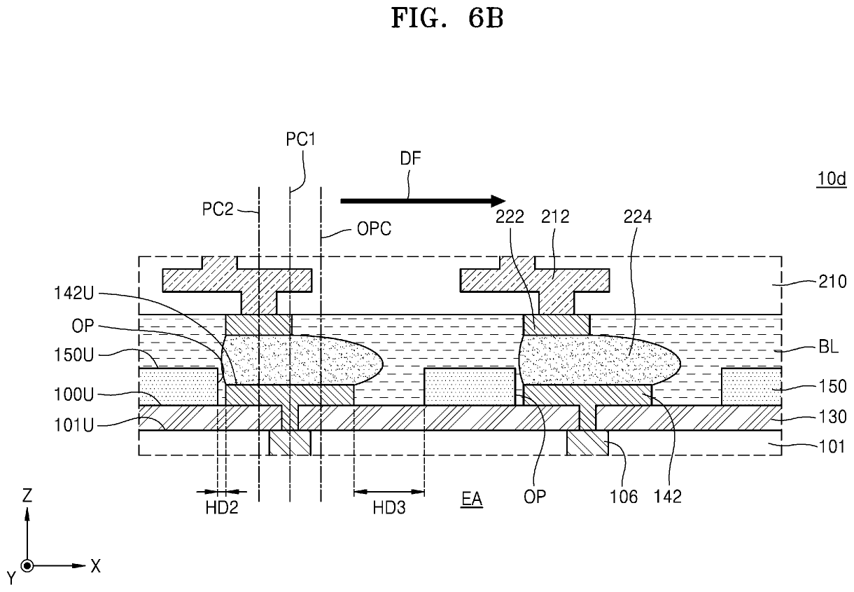

FIGS. 6A and 6B are a plan view and a cross-sectional view of a semiconductor package 10d, respectively, according to some embodiments. Referring to FIG. 6A, portions corresponding to the local regions indicated as EXA, EXB, EXC, and EXD in FIG. 1A are illustrated in (a), (b), (c), and (d), respectively. Referring to FIG. 6B, a portion corresponding to the local region indicated as EX2 in FIG. 2A is illustrated. Elements indicated in FIGS. 6A and 6B with the same reference numerals as those in FIGS. 1A to 2C and 4A to 5B may denote the same elements, and as such, repeated descriptions thereof described above with reference to FIGS. 1A to 2C and 4A to 5B may be omitted for the sake of brevity.

Referring to FIGS. 6A and 6B, the configuration of semiconductor package 10d may be similar in many respects to the configuration of the semiconductor package 10 described above with reference to FIGS. 1A to 2C, 4A, and 4B, and may include additional features not mentioned above. For example, in the edge region EA, the second pad center PC2 of the semiconductor package 10d may be located closer to the first chip center CC1 than the first pad center PC1 is located to the first chip center CC1.

According to some embodiments, in the edge region EA, the second pad center PC2 may be spaced apart from the first pad center PC1 in a direction toward the first chip center CC1. According to some embodiments, the opening center OPC, the first pad center PC1, and the second pad center PC2 may be spaced apart from one another, and the second pad center PC2, the first pad center PC1, and the opening center OPC may be arranged in an order based on a direction away from the first chip center CC1 (e.g., the flow direction DF). For example, the second pad center PC2, the first pad center PC1, and the opening center OPC may be arranged, based on the flow direction DF, in the following order: the second pad center PC2, the first pad center PC1, and the opening center OPC.

According to some embodiments, a third separation distance from the first pad center PC1 to the second pad center PC2 and a fourth separation distance from the first pad center PC1 to the opening center OPC may vary depending on distances from the first chip center CC1. For example, the third separation distance and the fourth separation distance in the first region adjacent to the first chip center CC1 may be smaller than the third separation distance and the fourth separation distance in the second region relatively far from the first chip center CC1 than the first region is, respectively.

Although FIGS. 6A and 6B show that the third separation distance and the fourth separation distance may be the same in all of local regions shown in FIGS. 6A and 6B, the present disclosure is not limited thereto. For example, the third separation distance and the fourth separation distance may gradually increase as the distance from the first chip center CC1 increases. As another example, the third separation distance and the fourth separation distance may each be proportional to the distance from the first chip center CC1.

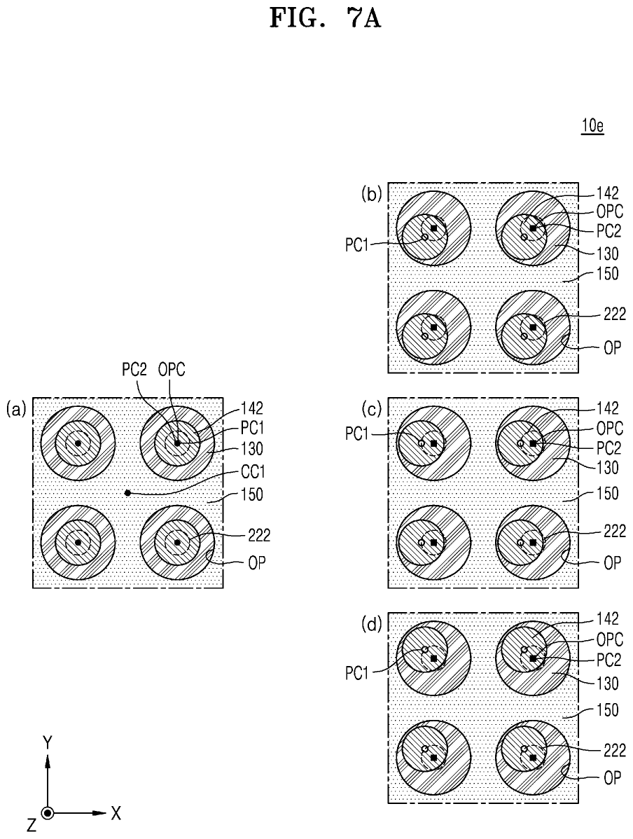

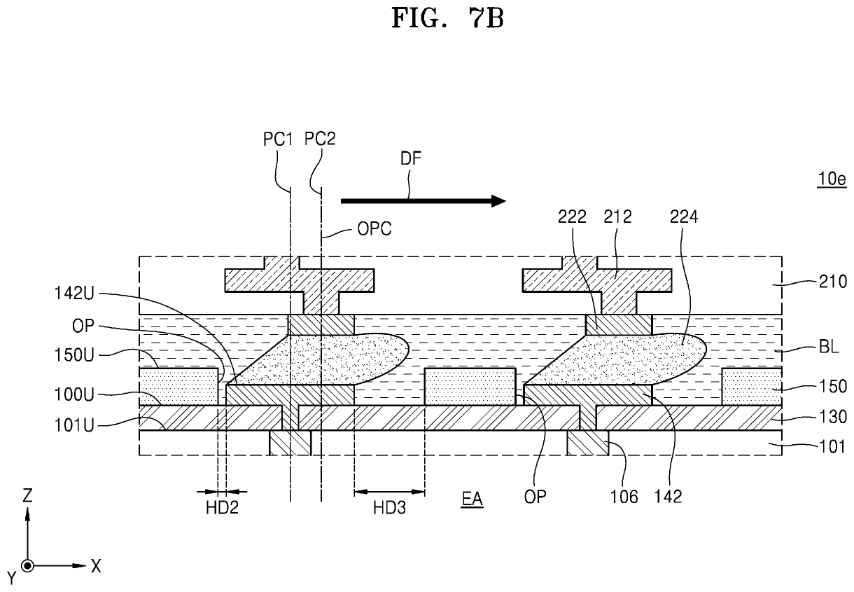

FIGS. 7A and 7B are a plan view and a cross-sectional view of a semiconductor package 10e, respectively, according to some embodiments. Referring to FIG. 7A, portions corresponding to the local regions indicated as EXA, EXB, EXC, and EXD in FIG. 1A are illustrated in (a), (b), (c), and (d), respectively. Referring to FIG. 7B, a portion corresponding to the local region indicated as EX2 in FIG. 2A is illustrated. Elements indicated in FIGS. 7A and 7B with the same reference numerals as those in FIGS. 1A to 2C and 4A to 6B may denote the same elements, and as such, repeated descriptions thereof described above with reference to FIGS. 1A to 2C and 4A to 6B may be omitted for the sake of brevity.

Referring to FIGS. 7A and 7B, the configuration of semiconductor package 10e may be similar in many respects to the configuration of the semiconductor package 10d described above with reference to FIGS. 6A and 6B, and may include additional features not mentioned above. For example, in the edge region EA, the first pad center PC1 of the semiconductor package 10e may be located closer to the first chip center CC1 than the second pad center PC2 and the opening center OPC are located to the first chip center CC1.

According to some embodiments, in the edge region EA, the second pad center PC2 may be spaced apart from the first pad center PC1 in the flow direction DF. Although FIG. 7B shows that the second pad center PC2 and the opening center OPC may overlap each other, the present disclosure is not limited thereto. According to some embodiments, the second pad center PC2 and the opening center OPC may be spaced apart from each other in the flow direction DF. For example, in the flow direction DF, the second pad center PC2 and the opening center OPC may be arranged in the following order: the first pad center PC1, the second pad center PC2, and the opening center OPC. As another example, in the flow direction DF, the second pad center PC2 and the opening center OPC may be arranged in the following order: the first pad center PC1, the opening center OPC, and the second pad center PC2.

According to some embodiments, in the edge region EA, each of the plurality of second lower pads 222 may be disposed farther away from the first chip center CC1 than a corresponding first upper pad 142 from among the plurality of first upper pads 142. When the first semiconductor chip 100 and the second semiconductor chip 200 are bonded to each other, the plurality of chip connecting terminals 224 may be seated on portions of the top surfaces 142U of the plurality of first upper pads 142 far from the first chip center CC1 and then spread toward the first chip center CC1 through wetting at the interface between the plurality of chip connecting terminals 224 and the top surfaces 142U of the plurality of first upper pads 142. Consequently, consumption of the plurality of chip connecting terminals 224 may be induced, and as a result, the size of portions of the plurality of chip connecting terminals 224 spreading in the flow direction DF may be reduced, when compared to related semiconductor packages.

According to some embodiments, a fifth separation distance from the second pad center PC2 to the first pad center PC1 and the opening center OPC may vary depending on the distance from the first chip center CC1. For example, the fifth separation distance in the first region adjacent to the first chip center CC1 may be smaller than the fifth separation distance in the second region relatively far from the first chip center CC1 than the first region is.

Although FIGS. 7A and 7B show that the fifth separation distance may be the same in all of local regions shown in FIGS. 7A and 7B, the present disclosure is not limited thereto. For example, the fifth separation distance may gradually increase as the distance from the first chip center CC1 increases. As another example, the fifth separation distance may be proportional to the distance from the first chip center CC1.

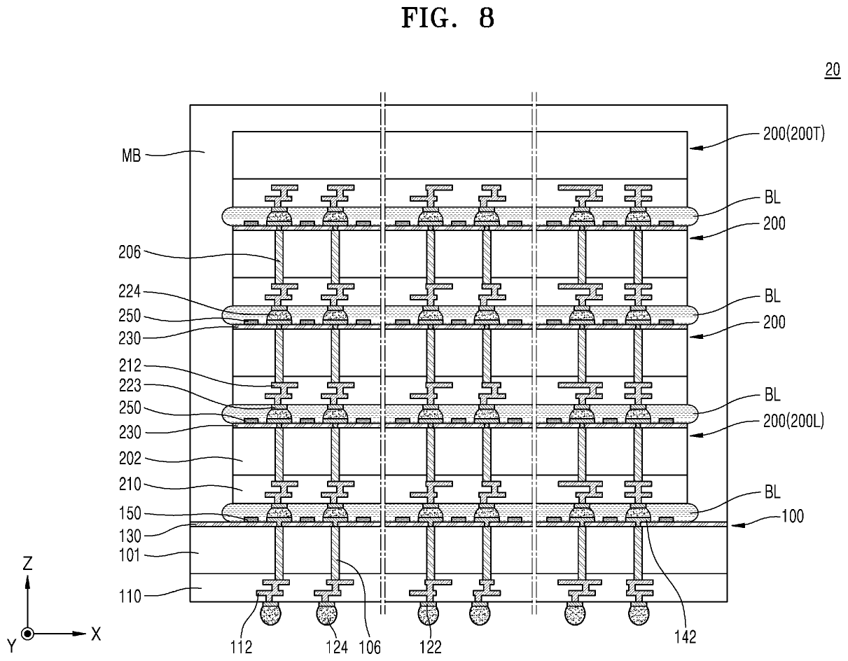

FIG. 8 is a cross-sectional view of a semiconductor package 20, according to some embodiments. Elements indicated in FIG. 8 with the same reference numerals as those in FIGS. 1A to 7B may denote the same elements, and as such, repeated descriptions thereof described above with reference to FIGS. 1A to 7B may be omitted for the sake of brevity.

Referring to FIG. 8, the semiconductor package 20 may include the first semiconductor chip 100 and the plurality of second semiconductor chips 200, which may be sequentially stacked on the first semiconductor chip 100.

Although FIG. 8 shows that the semiconductor package 20 includes a first semiconductor chip 100 and four (4) second semiconductor chips 200, the present disclosure is not limited thereto. For example, the semiconductor package 20 may include more (e.g., more than four (4)) and/or less (e.g., less than four (4)) second semiconductor chips 200. According to some embodiments, the number of second semiconductor chips 200 included in the semiconductor package 20 may be a multiple of four (4).

According to some embodiments, the first semiconductor chip 100 may be and/or may include a buffer chip for controlling HBM DRAM, and the plurality of second semiconductor chips 200 may be and/or may include memory cell chips having HBM DRAM cells controlled by the first semiconductor chip 100. The first semiconductor chip 100 may be referred to as a buffer chip and/or a master chip, and the second semiconductor chip 200 may be referred to as a memory cell chip and/or a slave chip. The first semiconductor chip 100 and the plurality of second semiconductor chips 200 stacked on the first semiconductor chip 100 may be collectively referred to as HBM DRAM devices and/or HBM DRAM chips.

The configurations of the first semiconductor chip 100 and the plurality of second semiconductor chips 200 may be similar in many respects and/or may be substantially the same configurations as those of the first semiconductor chip 100 and the second semiconductor chip 200 of the semiconductor package 10 described with reference to FIGS. 1A to 2C, and may include additional features not mentioned above. For example, the plurality of second semiconductor chips 200 of the semiconductor package 20 may be stacked in the vertical direction, and the plurality of second semiconductor chips 200 may further include a plurality of second via electrodes 206, a second upper protective layer 230, and a plurality of second upper pads 242. According to some embodiments, an uppermost second semiconductor chip 200T disposed farthest from the first semiconductor chip 100 from among the plurality of second semiconductor chips 200 may not include the plurality of second upper pads 242 and the plurality of second via electrodes 206.

According to some embodiments, different semiconductor chips stacked in the vertical direction may be connected to each other through the plurality of chip connecting terminals 224. The plurality of chip connecting terminals 224 may be arranged between the first semiconductor chip 100 and a lowermost second semiconductor chip 200L from among the plurality of second semiconductor chips 200 and between two (2) second semiconductor chips 200 adjacent to each other from among the plurality of second semiconductor chips 200.

According to some embodiments, the plurality of chip connecting terminals 224 may contact and be connected to the plurality of first upper pads 142 of the first semiconductor chip 100 and the plurality of second lower pads 222 of the second semiconductor chip 200 between the first semiconductor chip 100 and the semiconductor chip 200. According to some embodiments, between two (2) second semiconductor chips 200 adjacent to each other in the vertical direction (e.g., Z direction), the plurality of chip connecting terminals 224 may contact and be connected to the plurality of second upper pads 242 of a lower second semiconductor chip 200 and the plurality of second lower pads 222 of an upper second semiconductor chip 200. According to some embodiments, a non-conductive support layer 150 having the plurality of openings OP may be disposed on the top surface of a lower semiconductor chip of two (2) semiconductor chips adjacent to each other in the vertical direction. The plurality of chip connecting terminals 224 may extend through a corresponding opening OP from among the plurality of openings OP and may contact and be connect to pads adjacent thereto in the vertical direction.

In non-bonding regions of the first semiconductor chip 100 and the second semiconductor chip 200, the non-conductive support layer 150, the plurality of first upper pads 142, the plurality of second lower pads 222, and the plurality of chip connecting terminals 224 may have characteristics substantially similar and/or the same as to those of corresponding components in semiconductor packages 10, 10a, 10b, 10c, 10d, and 10e described with reference to FIGS. 1 to 7B. Alternatively or additionally, in bonding regions of two (2) second semiconductor chips 200 adjacent to each other, the non-conductive support layer 150, the second upper pads 242 of a lower second semiconductor chip 200, the second upper pads 242 of an upper second semiconductor chip 200, and the plurality of chip connecting terminals 224 may have characteristics substantially similar and/or the same as to those of corresponding components in the semiconductor packages 10, 10a, 10b, 10c, 10d, and 10e described with reference to FIGS. 1 to 7B. For example, the plurality of second lower pads 222 may have the second horizontal width W2, and the plurality of second upper pads 242 may have the first horizontal width W1, as described with reference to FIGS. 2B and 2C.

According to some embodiments, the insulation adhesive layer BL may be disposed between different semiconductor chips stacked in the vertical direction. For example, the insulation adhesive layer BL may be disposed between the first semiconductor chip 100 and the lowermost second semiconductor chip 200L from among the plurality of second semiconductor chips 200 and between two (2) second semiconductor chips 200 adjacent to each other from among the plurality of second semiconductor chips 200. The insulation adhesive layer BL may protrude from the sidewalls of the plurality of second semiconductor chips 200.

According to some embodiments, the semiconductor package 20 may include the mold layer MB surrounding the plurality of second semiconductor chips 200 and a plurality of insulation adhesive layers BL on the first semiconductor chip 100. According to some embodiments, the mold layer MB may cover side surfaces of the plurality of second semiconductor chips 200, side surfaces of the plurality of insulation adhesive layers BL, and the top surface of the uppermost second semiconductor chip 200T from among the plurality of second semiconductor chips 200 together. According to some embodiments, the mold layer MB may cover the side surfaces of the plurality of second semiconductor chips 200 and the side surfaces of the plurality of insulation adhesive layers BL and/or may not cover the top surface of the uppermost second semiconductor chip 200T from among the plurality of second semiconductor chips 200. For example, the top surface of the mold layer MB and the top surface of the uppermost second semiconductor chip 200T may be coplanar.

While the present disclosure has been particularly shown and described with reference to embodiments thereof, it is to be understood that various changes in form and details may be made therein without departing from the spirit and scope of the following claims.

What is claimed is:

1. A semiconductor package, comprising:
a first semiconductor chip comprising a plurality of upper pads;
a non-conductive support layer on a top surface of the first semiconductor chip and comprising a plurality of openings;
a second semiconductor chip on the first semiconductor chip and comprising a plurality of lower pads;
a plurality of chip connecting terminals extending between the plurality of upper pads and the plurality of lower pads; and
an insulation adhesive layer between the first semiconductor chip and the second semiconductor chip and at least partially covering the plurality of chip connecting terminals and the non-conductive support layer,
wherein each of the plurality of chip connecting terminals is coupled with a corresponding upper pad from among the plurality of upper pads and a corresponding lower pad from among the plurality of lower pads through a corresponding opening from among the plurality of openings of the non-conductive support layer,
wherein each of the plurality of upper pads comprises a first horizontal area,
wherein each of the plurality of lower pads comprises a second horizontal area,
wherein the first horizontal area is larger than the second horizontal area, and
wherein a top surface of the non-conductive support layer is disposed closer to a bottom surface of the second semiconductor chip than top surfaces of the plurality of upper pads are disposed to the bottom surface of the second semiconductor chip.

2. The semiconductor package of claim 1, wherein a distance between the top surface of the first semiconductor chip and the bottom surface of the second semiconductor chip in a vertical direction has a first length,
wherein a thickness of the non-conductive support layer in the vertical direction has a second length, and
wherein the second length is less than or equal to a half of the first length.

3. The semiconductor package of claim 1, wherein the non-conductive support layer is spaced apart from the plurality of upper pads.

4. The semiconductor package of claim 1, wherein the non-conductive support layer at least partially covers sidewalls of the plurality of upper pads and edge portions of the top surfaces of the plurality of upper pads.

5. The semiconductor package of claim 1, wherein, in a plan view, the second semiconductor chip comprises a first chip center, a center region comprising the first chip center, and an edge region at least partially surrounding the center region,
wherein each of the plurality of openings of the non-conductive support layer has an opening center,
wherein each of the plurality of upper pads comprises a first pad center,
wherein each of the plurality of lower pads comprises a second pad center,
wherein, in the center region, the opening center, the first pad center, and the second pad center at least partially overlap one another, and
wherein, in the edge region, in the plan view, at least one of the opening center, the first pad center, and the second pad center is spaced apart from remaining centers of the at least one of the opening center, the first pad center, and the second pad center in a direction away from the first chip center.

6. The semiconductor package of claim 1, wherein, in a plan view, the second semiconductor chip comprises a first chip center, a center region comprising the first chip center, and an edge region at least partially surrounding the center region,
wherein an inner wall of each of the plurality of openings is spaced apart from each of the plurality of upper pads,
wherein a sidewall of each of the plurality of upper pads comprises a first portion facing the first chip center and a second portion opposite to the first portion, and
wherein, in the edge region, a first distance between the first portion and a corresponding inner wall of the plurality of openings is less than a second distance between the second portion and the corresponding inner wall.

7. The semiconductor package of claim 6, wherein, in the center region, the first distance is equal to the second distance.

8. The semiconductor package of claim 6, wherein, in the edge region, a difference between the first distance and the second distance is proportional to a distance from the first chip center.

9. The semiconductor package of claim 1, wherein, in a plan view, the second semiconductor chip comprises a first chip center, a center region comprising the first chip center, and an edge region at least partially surrounding the center region,
wherein each of the plurality of openings of the non-conductive support layer comprises an opening center,
wherein each of the plurality of upper pads comprises a first pad center, and
wherein, in the edge region, a first distance between the first pad center of each of the plurality of upper pads and the first chip center is less than a second distance between the opening center of the corresponding opening from among the plurality of openings and the first chip center.

10. The semiconductor package of claim 1, wherein, in a plan view, the second semiconductor chip comprises a first chip center, a center region comprising the first chip center, and an edge region at least partially surrounding the center region,
wherein each of the plurality of upper pads comprises a first pad center,
wherein each of the plurality of lower pads comprises a second pad center, and
wherein, in the edge region, a first distance between the second pad center of each of the plurality of lower pads and the first chip center is less than a second distance between the first pad center of the corresponding upper pad from among the plurality of upper pads and the first chip center.

11. The semiconductor package of claim 1, wherein the insulation adhesive layer protrudes from sidewalls of the second semiconductor chip.

12. The semiconductor package of claim 1, wherein, in a plan view, a first boundary of a first opening from among the plurality of openings, a second boundary of the corresponding upper pad from among the plurality of upper pads, and a third boundary of the corresponding lower pad from among the plurality of lower pads comprise concentric circular shapes.

13. A semiconductor package, comprising:
a first semiconductor chip comprising a plurality of upper pads;
a non-conductive support layer on a top surface of the first semiconductor chip and comprising a plurality of openings at least partially exposing the plurality of upper pads;
a second semiconductor chip on the first semiconductor chip and comprising a plurality of lower pads; and
a plurality of chip connecting terminals, each of the plurality of chip connecting terminals contacting and coupled with an upper pad from among the plurality of upper pads and a lower pad from among the plurality of lower pads,
wherein each of the plurality of upper pads has a first horizontal width,
wherein each of the plurality of lower pads has a second horizontal width,
wherein the second horizontal width is less than the first horizontal width,
wherein, in a plan view, the second semiconductor chip comprises a first chip center, a center region comprising the first chip center, and an edge region at least partially surrounding the center region,
wherein each of the plurality of openings of the non-conductive support layer comprises an opening center,
wherein each of the plurality of upper pads comprises a first pad center,
wherein each of the plurality of lower pads comprises a second pad center, and
wherein, in the edge region, in the plan view, at least one of the opening center, the first pad center, and the second pad center is spaced apart from remaining centers of the at least one of the opening center, the first pad center, and the second pad center in a direction away from the first chip center.

14. The semiconductor package of claim 13, wherein, in the center region, the opening center, the first pad center, and the second pad center at least partially overlap one another.

15. The semiconductor package of claim 13, wherein an inner wall of each of the plurality of openings is spaced apart from each of the plurality of upper pads,
wherein a sidewall of each of the plurality of upper pads comprises a first portion facing the first chip center and a second portion opposite to the first portion, and
wherein, in the edge region, a first distance between the first portion and a corresponding inner wall of the plurality of openings is less than a second distance between the second portion and the corresponding inner wall.

16. The semiconductor package of claim 13, wherein, in the edge region, the opening center, the first pad center, and the second pad center are spaced apart from one another, and
wherein the second pad center, the first pad center, and the opening center are disposed in the direction away from the first chip center, based on a flow direction.

17. The semiconductor package of claim 13, wherein, in the edge region, a first distance between the first pad center and the first chip center is less than a second distance between the second pad center and the first chip center.

18. A semiconductor package, comprising:
a first semiconductor chip comprising a plurality of upper pads;
a non-conductive support layer on a top surface of the first semiconductor chip and comprising a plurality of openings at least partially exposing the plurality of upper pads;
a second semiconductor chip on the first semiconductor chip and comprising a plurality of lower pads;
a plurality of chip connecting terminals, each of the plurality of chip connecting terminals contacting and coupled with an upper pad from among the plurality of upper pads and a lower pad from among the plurality of lower pads; and
an insulation adhesive layer, between the first semiconductor chip and the second semiconductor chip, at least partially covering the plurality of chip connecting terminals and the non-conductive support layer, and protruding from sidewalls of the second semiconductor chip,
wherein each of the plurality of upper pads has a first horizontal area,
wherein each of the plurality of lower pads has a second horizontal area,
wherein the first horizontal area is larger than the second horizontal area,
wherein a top surface of the non-conductive support layer is disposed closer to a bottom surface of the second semiconductor chip than top surfaces of the plurality of upper pads are disposed to the bottom surface of the second semiconductor chip, and
wherein a first length between the top surface of the non-conductive support layer and the bottom surface of the second semiconductor chip in a vertical direction is less than or equal to a half of a second length between the top surface of the first semiconductor chip and the bottom surface of the second semiconductor chip.

19. The semiconductor package of claim 18, wherein, in a plan view, the second semiconductor chip comprises a first chip center, a center region comprising the first chip center, and an edge region surrounding the center region,
wherein each of the plurality of openings of the non-conductive support layer comprises an opening center,
wherein each of the plurality of upper pads comprises a first pad center, and
wherein, in the edge region, a first distance between the first pad center of each of the plurality of upper pads and the first chip center is less than a second distance between the opening center of a corresponding opening from among the plurality of openings and the first chip center.

20. The semiconductor package of claim 18, wherein, in a plan view, the second semiconductor chip comprises a first chip center, a center region comprising the first chip center, and an edge region surrounding the center region,
wherein an inner wall of each of the plurality of openings is spaced apart from each of the plurality of upper pads,
wherein a sidewall of each of the plurality of upper pads comprises a first portion facing the first chip center and a second portion opposite to the first portion, and
wherein, in the edge region, a first distance between the first portion and a corresponding inner wall of the plurality of openings is less than a second distance between the second portion and the corresponding inner wall.
